(19) United States
(12) Patent Application Publication
(10) Pub. No.: US 2024/0039248 A1
(43) Pub. Date: Feb. 1, 2024

(54) SEMICONDUCTOR LASER DEVICE AND METHOD OF MANUFACTURING THE SAME

(71) Applicant: Sumitomo Electric Industries, Ltd., Osaka (JP)

(72) Inventor: Daisuke INOUE, Osaka (JP)

(73) Assignee: Sumitomo Electric Industries, Ltd., Osaka (JP)

(21) Appl. No.: 18/225,855

(22) Filed: Jul. 25, 2023

(30) Foreign Application Priority Data
Aug. 1, 2022 (JP) 2022-122614

(51) Int. Cl. H01S 5/34; H01S 5/227; H01S 5/343; H01S 5/22

(52) U.S. Cl. CPC H01S 5/3425; H01S 5/227; H01S 5/3434; H01S 5/34373; H01S 5/2206; H01S 5/2222

(57) ABSTRACT

A semiconductor laser device includes a first semiconductor layer and an active layer provided above the first semiconductor layer. The first semiconductor layer is a superlattice layer and includes a plurality of first layers and a plurality of second layers. The plurality first layers and the plurality of second layers are alternately stacked upon each other. Thicknesses of the plurality of first layers are equal to each other, and thicknesses of the plurality of second layers are equal to each other.

### CROSS-REFERENCE TO RELATED APPLICATION

This application claims priority based on Japanese Patent Application No. 2022-122614 filed on Aug. 1, 2022, and the entire contents of the Japanese patent application are incorporated herein by reference.

### FIELD

The present disclosure relates to a semiconductor laser device and a method of manufacturing the same.

### BACKGROUND

A light source used in optical communication or the like is required to have a high optical output. A semiconductor laser device is used as the light source. Patent Literature 1 (U.S. Patent Application Publication No. 2015/0103858) discloses a semiconductor laser device including a semiconductor layer for controlling a distribution of light, an active layer, and a p-type semiconductor layer. In such a semiconductor laser device, distributing light in the semiconductor layer below the active layer allows light to be kept away from the active layer and the p-type semiconductor layer that have large light absorption to suppress a light absorption. This results in a higher output.

### SUMMARY

A semiconductor laser device according to the present disclosure includes a first semiconductor layer and an active layer provided on the first semiconductor layer. The first semiconductor layer is a superlattice layer and includes a plurality of first layers and a plurality of second layers. The plurality first layers and the plurality of second layers are alternately stacked upon each other. Thicknesses of the plurality of first layers are equal to each other, and thicknesses of the plurality of second layers are equal to each other.

A method of manufacturing a semiconductor laser device according to the present disclosure includes providing a first semiconductor layer, measuring a thickness of the first semiconductor layer by X-ray diffraction, and providing an active layer onto the first semiconductor layer after the measuring the thickness is performed. The first semiconductor layer is a superlattice layer and includes a plurality of first layers and a plurality of second layers. The plurality first layers and the plurality of second layers are alternately stacked upon each other. Thicknesses of the plurality of first layers are equal to each other, and thicknesses of the plurality of second layers are equal to each other.

### BRIEF DESCRIPTION OF THE DRAWINGS

FIG. 1 is a plan view illustrating a semiconductor laser device.

FIG. 2A is a cross-sectional view illustrating the semiconductor laser device.

FIG. 2B is an enlarged view of a core layer.

FIG. 3 is a flow chart illustrating a method of manufacturing the semiconductor laser device.

FIG. 4A is a cross-sectional view illustrating a method of manufacturing the semiconductor laser device.

FIG. 4B is a cross-sectional view illustrating a method of manufacturing the semiconductor laser device.

FIG. 5A is a cross-sectional view illustrating a method of manufacturing the semiconductor laser device.

FIG. 5B is a cross-sectional view illustrating a method of manufacturing the semiconductor laser device.

FIG. 6A is a cross-sectional view illustrating a method of manufacturing the semiconductor laser device.

FIG. 6B is a cross-sectional view illustrating a method of manufacturing the semiconductor laser device.

FIG. 7A is a schematic diagram illustrating a rocking curve of X-ray diffraction.

FIG. 7B is a diagram illustrating a relationship between a period of a core layer and a diffraction angle of a first order peak.

### DETAILED DESCRIPTION

Since a thickness of a semiconductor layer affects optical characteristics, it is important to evaluate the thickness. Therefore, an object of the present disclosure is to provide a semiconductor laser device that allows evaluation of a thickness of a semiconductor layer, and a method of manufacturing the same.

First, the contents of embodiments of the present disclosure will be listed and described.

(1) An embodiment according to the present disclosure is a semiconductor laser device that includes a first semiconductor layer and an active layer provided above the first semiconductor layer. The first semiconductor layer is a superlattice layer and includes a plurality of first layers and a plurality of second layers. The plurality first layers and the plurality of second layers are alternately stacked upon each other. Thicknesses of the plurality of first layers are equal to each other, and thicknesses of the plurality of second layers are equal to each other. Since the first semiconductor layer has a periodic structure, the period of the first semiconductor layer can be measured by X-ray diffraction. The thickness of the first semiconductor layer can be evaluated based on the period.

(2) In the above (1), the first layer may be formed of indium phosphide, and the second layer may be formed of indium gallium arsenide phosphide or aluminum indium gallium arsenide. Since the first semiconductor layer has the periodic structure, the period of the first semiconductor layer can be measured by X-ray diffraction.

(3) In the above (1) or (2), the semiconductor laser device may further include a second semiconductor layer provided on the active layer, and a refractive index of the first semiconductor layer may be higher than a refractive index of the second semiconductor layer. Since light generated in the active layer is distributed in the first semiconductor layer, absorption by the active layer is suppressed. This allows for a higher output power of the semiconductor laser device.

(4) In any one of the above (1) to (3), each of the thicknesses of the first layers and the thicknesses of the second layers may be 10 nm or more. This allows the first semiconductor layer to have stabilized physical properties.

(5) In any one of the above (1) to (4), the first semiconductor layer may have a thickness of 1 μm or more. This allows light to be distributed in the first semiconductor layer and kept away from the active layer to suppress light absorption.

(6) In any one of the above (1) to (5), the active layer may form a mesa, and the first semiconductor layer may have a width larger than a width of the mesa. This allows the first semiconductor layer to have a higher effective refractive index to transfer light into the first semiconductor layer, resulting in suppression of light absorption.

(7) In any one of the above (1) to (6), the semiconductor laser device may further include a second semiconductor layer provided above the active layer. A conductive type of the first semiconductor layer may be n-type, and a conductive type of the second semiconductor layer may be p-type. This allows light to be distributed in the first semiconductor layer and kept away from the second semiconductor layer, resulting in suppression of light absorption by the p-type second semiconductor layer.

(8) In the above (6), the semiconductor laser device may further include a buried layer provided on both sides of the mesa. This allows the buried layer to block a current to selectively supply the current to a mesa 11.

(9) A method of manufacturing a semiconductor laser device includes providing a first semiconductor layer, measuring a thickness of the first semiconductor layer by X-ray diffraction, and providing an active layer above the first semiconductor layer after the measuring the thickness. The first semiconductor layer is a superlattice layer and includes a plurality of first layers and a plurality of second layers. The plurality of first layers and the plurality of second layers are alternately stacked upon each other. Thicknesses of the plurality of first layers are equal to each other, and thicknesses of the plurality of second layers are equal to each other. Since the first semiconductor layer has the periodic structure, the period of the first semiconductor layer can be measured by X-ray diffraction. The thickness of the first semiconductor layer can be evaluated based on the measurement of the period.

### DETAILS OF EMBODIMENTS OF THE PRESENT DISCLOSURE

Specific examples of a semiconductor laser device and a manufacturing method thereof according to an embodiment of the present disclosure will be described below with reference to the drawings. The present disclosure is not limited to these examples, and is defined by the scope of the claims, and is intended to include all modifications within the meaning and scope equivalent to the scope of the claims.

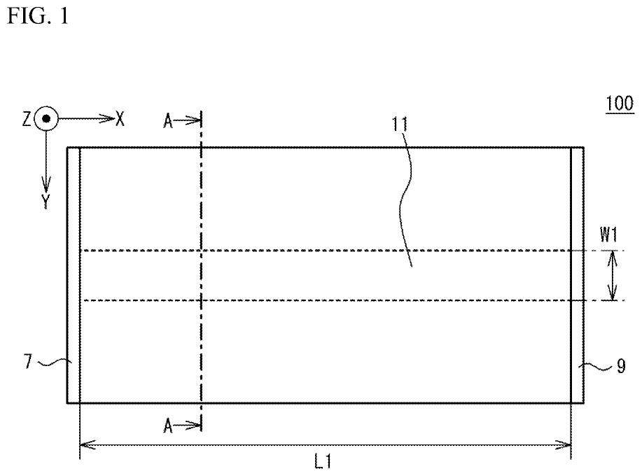

FIG. 1 is a plan view illustrating a semiconductor laser device 100. Semiconductor laser device 100 is a distributed feedback (DFB) laser device. An X-axis represents a direction in which light propagates. A Y-axis represents a width direction of a mesa 11. A Z-axis represents a direction in which a semiconductor layer is stacked. X-axis, Y-axis, and Z-axis are orthogonal to each other. In FIG. 1, mesa 11 is illustrated through an electrode and an insulating film.

A length L1 of semiconductor laser device 100 in X-axis direction is, for example, 800 μm. A high-reflection film 7 (HR: High reflection) is provided on one end face of semiconductor laser device 100 in X-axis direction. An antireflection film 9 (AR: Anti reflection) is provided on the other end face in X-axis direction.

Semiconductor laser device 100 includes mesa 11. Mesa 11 is located in the center in Y-axis direction. Mesa 11 extends in X-axis direction from the one end face to the other end face of semiconductor laser device 100. Light is generated in mesa 11 and propagates in X-axis direction. The light is reflected by high-reflection film 7, passes through antireflection film 9, and is emitted to the outside of semiconductor laser device 100. Mesa 11 has a width W1 of, for example, 2.4 μm in Y-axis direction.

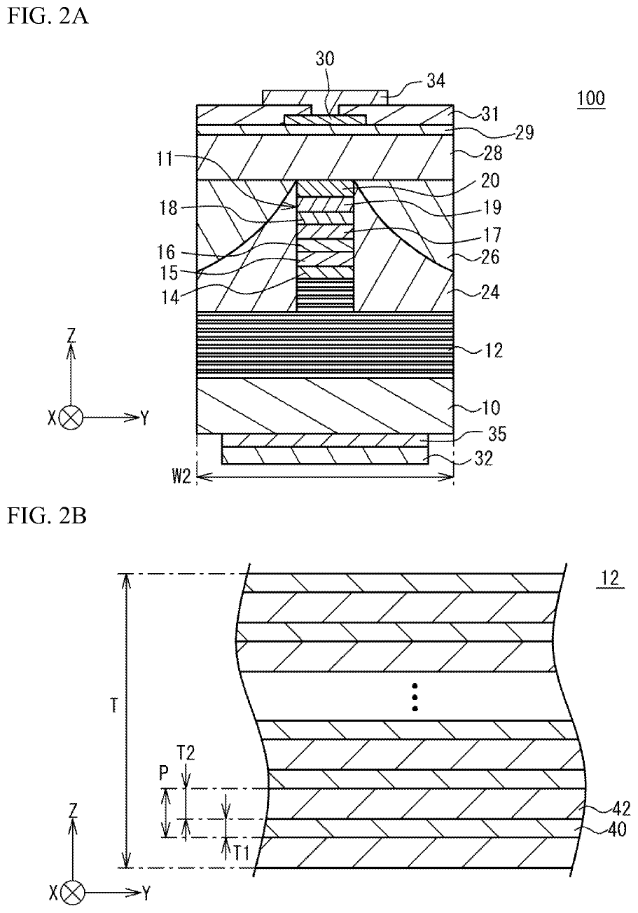

FIG. 2A is a cross-sectional view illustrating semiconductor laser device 100, illustrating a cross-section taken along line A-A in FIG. 1. Semiconductor laser device 100 includes a substrate 10 and a core layer 12. Core layer 12 (first semiconductor layer) is stacked on substrate 10.

Mesa 11 includes core layer 12, a cladding layer 14, a diffraction grating layer a cladding layer 16, a guide layer 17, an active layer 18, a guide layer 19, and a cladding layer 20. A cross-sectional shape of core layer 12 is a convex shape. Core layer 12 has a protruding portion in the center in Y-axis direction. Cladding layer 14, diffraction grating layer 15, cladding layer 16, guide layer 17, active layer 18, guide layer 19, and cladding layer 20 are stacked in this order on the protruding portion of core layer 12 to form mesa 11.

Recesses and projections are provided on a top surface of diffraction grating layer 15. The plurality of recesses and projections are periodically arranged along X-axis. Cladding layer 16 is buried in recessed portions (recesses) of diffraction grating layer 15. The recesses and projections of diffraction grating layer 15 function as a diffraction grating.

Surfaces of core layer 12 on both sides of mesa 11 are recessed from mesa 11. A buried layer 24 and a buried layer 26 are stacked in this order on the surfaces of core layer 12 on both sides of mesa 11. Buried layer 24 and buried layer 26 are provided on both sides of mesa 11.

Cladding layer 20 and a cladding layer 28 (second semiconductor layer) are provided above active layer 18 and guide layer 19. Cladding layer 20 is included in mesa 11. Cladding layer 28 is stacked on mesa 11 and buried layer 26. A contact layer 29 is stacked on cladding layer 28. Cladding layer 28 and contact layer 29 cover mesa 11 and buried layer 26.

An electrode 30 is provided directly above mesa 11 on a top surface of contact layer 29. An insulating film 31 is provided on contact layer 29 and electrode 30. Insulating film 31 has an opening above electrode 30. A top surface of electrode 30 is exposed from the opening. A wiring layer 34 is provided directly above mesa 11 on a top surface of insulating film 31. Wiring layer 34 is in contact with the top surface of electrode 30 through the opening of insulating film 31, and is electrically connected to electrode 30. Electrode 30 and wiring layer 34 are electrically connected to contact layer 29. Electrode 30 is formed of a metal such as a laminate (Ti/Pt/Au) of titanium, platinum, and gold. Wiring layer 34 is formed of, for example, gold (Au).

A contact layer 35 is provided on a bottom surface of substrate 10 (a surface of substrate 10 opposite to the surface on which core layer 12 is provided). An electrode 32 is provided on a surface of contact layer 35 opposite to a surface of contact layer 35 in contact with substrate 10. Electrode 32 is electrically connected to contact layer 35. Electrode 32 is formed of a metal such as an alloy (AuGeNi) of gold, germanium and Ni.

Substrate 10 and contact layer 35 are formed of, for example, n-type indium phosphide (n-InP). Cladding layers 14 and 16 are formed of, for example, n-InP. For example, silicon (Si) is used as an n-type dopant. Dopant concentrations in cladding layers 14 and 16 are, for example, 5×10¹⁷ cm⁻³. Refractive indices of cladding layers 14 and 16 are, for example, 3.204. Bandgaps of cladding layers 14 and 16 are, for example, from 0.918 eV to 1 eV. Diffraction grating layer 15 is formed of, for example, indium gallium arsenide phosphide (InGaAsP).

Guide layers 17 and 19 are formed of, for example, non-doped indium gallium arsenide phosphide (i-InGaAsP). Refractive indices of guide layers 17 and 19 are, for example, 3.320. Active layer 18 has a multi quantum well structure (MQW). Active layer 18 includes a plurality of well layers and a plurality of barrier layers. The plurality of well layers and the plurality of barrier layers are alternately stacked upon each other. The well layers and the barrier layers are formed of, for example, i-InGaAsP. Refractive indices of the well layers are, for example, 3.435. Refractive indices of the barrier layers are, for example, 3.280.

Cladding layers 20 and 28 are formed of, for example, p-type indium phosphide (p-InP). Refractive indices of cladding layers 20 and 28 are, for example, 3.204. Contact layer 29 is formed of, for example, p+-type indium gallium arsenide ((p+)-InGaAs). For example, zinc (Zn) is used as a p-type dopant. A dopant concentration in cladding layer 28 is, for example, 1×10¹⁸ cm⁻³. A dopant concentration in contact layer 29 is higher than a dopant concentration in cladding layer 28.

Buried layer 24 is formed of, for example, p-InP. Buried layer 26 has a conductive type opposite to that of buried layer 24 and is formed of, for example, n-InP. Dopant concentrations of buried layers 24 and 26 are, for example, 4×10¹⁸ cm⁻³. Refractive indices of buried layers 24 and 26 are, for example, 3.204.

FIG. 2B is an enlarged view of core layer 12. A thickness T of entire core layer 12 is, for example, from 1 μm to 2 μm. As illustrated in FIG. 2B, core layer 12 is a superlattice layer and includes two types of semiconductor layers. Core layer 12 includes an indium phosphide layer 40 (InP layer 40, first layer) and an indium gallium arsenide phosphide layer 42 (InGaAsP layer 42, second layer). InP layer 40 and InGaAsP layer 42 have an n-type conductive type. Dopant concentrations (Si concentrations) of InP layer 40 and InGaAsP layer 42 are, for example, 5×10¹⁷ cm⁻³. A refractive index of InP layer 40 is, for example, 3.204. A refractive index of InGaAsP layer 42 is, for example, 3.320. An effective refractive index of core layer 12 as a whole is higher than the refractive indices of cladding layers 20 and 28. The effective refractive index of core layer 12 is calculated, for example, as follows. The product of the refractive index of InP layer 40 and the thickness of InP layer 40 is calculated. The product of the refractive index of InGaAsP layer 42 and the thickness of InGaAsP layer 42 is calculated.

An average refractive index is obtained by dividing the sum of the two products by the thickness of entire core layer 12. The average refractive index can be regarded as the effective refractive index. A bandgap of core layer 12 is larger than an energy of light (wavelength 1310 nm) generated in active layer 18.

A plurality of InP layers 40 and a plurality of InGaAsP layers 42 are alternately stacked upon each other. That is, one InGaAsP layer 42 is provided on a top surface of one InP layer 40. One InP layer 40 is provided on a top surface of one InGaAsP layer 42.

The thicknesses of the plurality of InP layers 40 are equal to each other. A thickness T1 of each of InP layers 40 is, for example, 15 nm. The thicknesses of the plurality of InGaAsP layers 42 are equal to each other. A thickness T2 of each of InGaAsP layers 42 is, for example, 30 nm. Pairs of InP layer 40 and InGaAsP layer 42 are stacked at a constant period to form core layer 12. A thickness of a pair of one InP layer 40 and one InGaAsP layer 42 may be referred to as a period P of core layer 12. The product of the number of pairs and period P is equal to thickness T of core layer 12. A portion of core layer 12 to be mesa 11 includes, for example, 10 pairs of InP layer 40 and InGaAsP layer 42. A portion of core layer 12 below mesa 11 includes, for example, pairs of InP layer 40 and InGaAsP layer 42.

Thickness T1 of one InP layer 40 and thickness T2 of one InGaAsP layer 42 can be measured using, for example, a transmission electron microscope (TEM). Period P of core layer 12 can be measured by X-ray diffraction (XRD).

A current is input to semiconductor laser device 100 through electrodes 30 and 32. An n-type core layer 12, a p-type buried layer 24, and an n-type buried layer 26 are stacked on both sides of mesa 11. Therefore, the current hardly flows to the outside of mesa 11, but easily flows to mesa 11. Carriers are injected into active layer 18, so that active layer 18 generates light. A wavelength of the light is, for example, 1.31 μm. The light propagates through mesa 11, is reflected by high-reflection film 7 at one end of semiconductor laser device 100, resulting in laser oscillation. Light is emitted from the other end of semiconductor laser device 100.

Active layer 18 and p-type cladding layer 28 are more likely to absorb light than an n-type semiconductor layer such as core layer 12. In semiconductor laser device 100, light is distributed in core layer 12 and kept away from active layer 18 and cladding layer 28. This allows suppression of light absorption, so that semiconductor laser device 100 functions as a high-power light source.

### (Manufacturing Method)

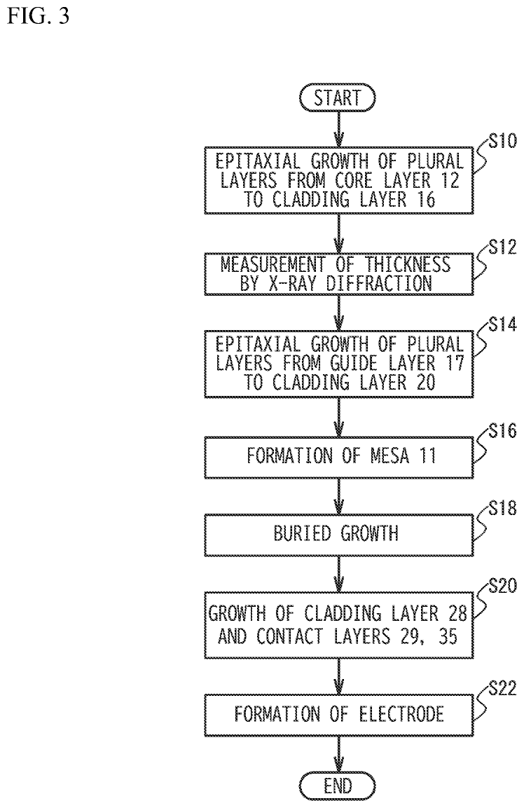

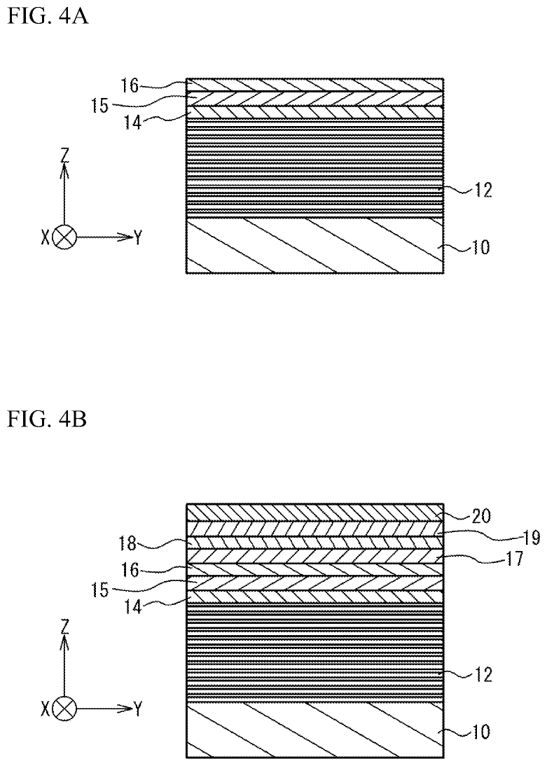

FIG. 3 is a flow chart illustrating a method of manufacturing semiconductor laser device 100. FIGS. 4A to 6B are cross-sectional views illustrating a method of manufacturing semiconductor laser device 100.

As illustrated in FIG. 4A, core layer 12, cladding layer 14, diffraction grating layer 15, and cladding layer 16 are epitaxially grown in this order on substrate 10 by, for example, a metal-organic chemical vapor deposition (MOCVD) method (step S10 in FIG. 3). A source gas for InP layers 40 and a source gas for InGaAsP layers 42 are supplied alternately to stack InP layers 40 and InGaAsP layers 42 alternately. After the growth of diffraction grating layer 15, recesses and projections are formed in diffraction grating layer by, for example, electron beam drawing and etching. Cladding layer 16 is grown after the formation of the recesses and projections. In this step, guide layers 17 and 19, active layer 18, cladding layer 20, and cladding layer 28 are not formed. Mesa 11 is not formed either.

A thickness of core layer 12 is measured (step S12 in FIG. 3). Specifically, core layer 12 is irradiated with, for example, CuKα rays (characteristic X-rays, wavelength: 1.541 Å) to perform X-ray diffraction. A period of core layer 12 is measured based on a rocking curve. The number of InP layers 40 and the number of InGaAsP layers 42 included in core layer 12 are determined in advance according to manufacturing conditions. Thickness T of core layer 12 can be determined based on a thickness (period) of one pair of InP layer 40 and InGaAsP layer 42 and the number of pairs. When thickness T is within a predetermined range, the steps subsequent to step S12 are performed. When thickness T is out of the predetermined range, the product is determined to be defective.

As illustrated in FIG. 4B, guide layer 17, active layer 18, guide layer 19, and cladding layer 20 are epitaxially grown on cladding layer 16 by an MOCVD method or the like (step S14 in FIG. 3).

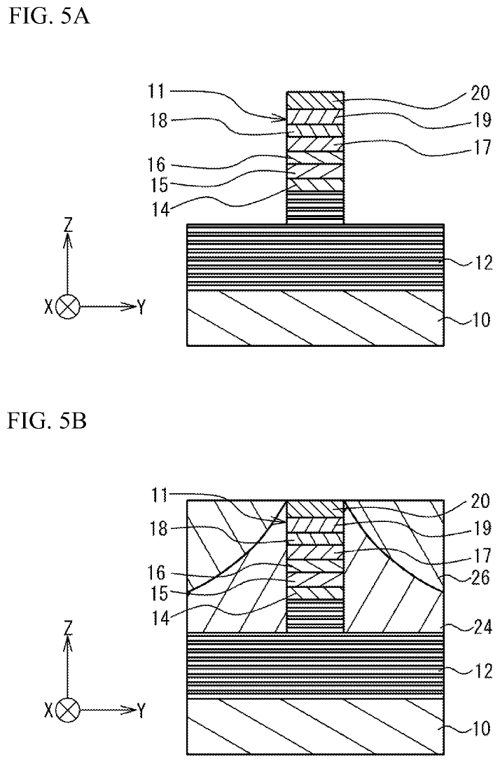

As illustrated in FIG. 5A, mesa 11 is formed by, for example, dry etching (step S16 in FIG. 3). A mask (not illustrated) is provided in a central portion on a top surface of cladding layer 20. A portion exposed from the mask is etched. Etching proceeds from cladding layer 20 to core layer 12 partway. Mesa 11 is formed in the central portion protected by the mask. A surface of core layer 12 is exposed on both sides of mesa 11. After the etching is finished, the mask is removed.

As illustrated in FIG. 5B, buried growth is performed on both sides of mesa 11 (step S18 in FIG. 3). Buried layer 24 and buried layer 26 are epitaxially grown in this order.

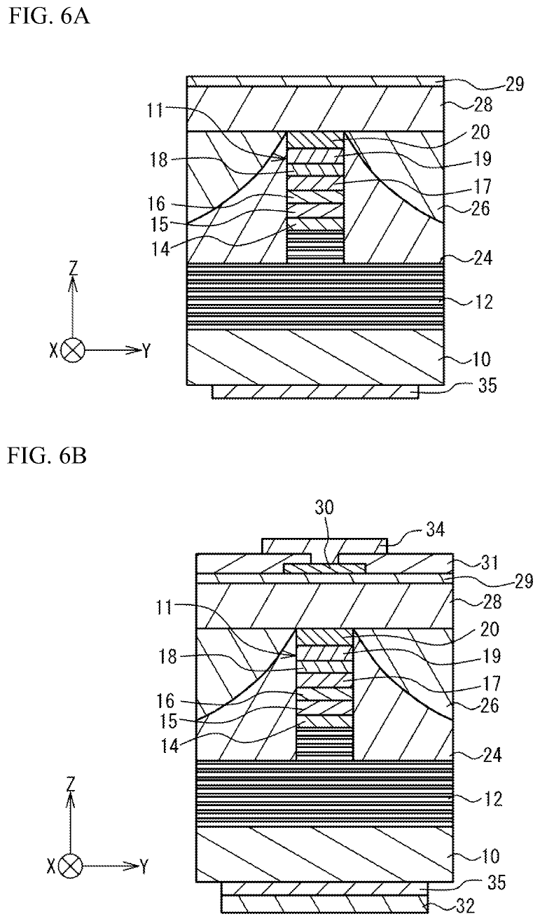

As illustrated in FIG. 6A, cladding layer 28 is epitaxially grown on the top surface of cladding layer 20 and a top surface of buried layer 26. Contact layer 29 is epitaxially grown on a top surface of cladding layer 28. Contact layer 35 is epitaxially grown on the bottom surface of substrate 10 (step S20 of FIG. 3).

As illustrated in FIG. 6B, electrode 30 is formed directly above mesa 11 on the top surface of contact layer 29 by, for example, vacuum deposition and lift-off. Electrode 32 is formed directly below mesa 11 on a bottom surface of contact layer 35. Insulating film 31 is formed on the top surface of contact layer 29 by, for example, a plasma CVD (Chemical Vapor Deposition) method. Wiring layer 34 is formed by plating or the like (step S22 in FIG. 3). Through the above steps, semiconductor laser device 100 is formed.

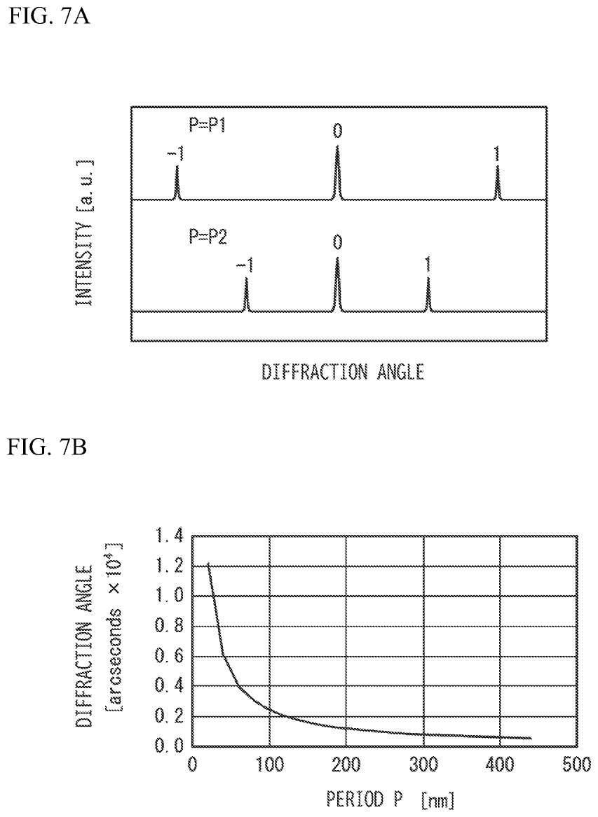

FIG. 7A is a schematic diagram illustrating a rocking curve of X-ray diffraction. A horizontal axis represents a diffraction angle. A vertical axis represents an X-ray intensity. Core layer 12 is irradiated with CuKα rays to measure a rocking curve illustrated in FIG. 7A. P represents a period in core layer 12. FIG. 7A illustrates a rocking curve for an example of P=P1 and a rocking curve for an example of P=P2. Period P1 is smaller than period P2.

The numbers (0, 1, −1) in FIG. 7A represent the order of peak. The zero order peak is a peak due to substrate 10. The first order peak is a peak caused by core layer 12. An angle between the zero order peak and the first order peak changes with period P. As period P increases, the first order peak becomes closer to the zero order peak. In the example of FIG. 7A, an interval between the peaks for period P=P2 is narrower than an interval between the peaks for period P=P1.

An angle of a satellite peak (first order peak in FIG. 7A) is expressed by the following equation. θ0 is a diffraction angle of the zero order peak. θn is a diffraction angle of the n-th order peak. n is the order of the peak, and n=1 for the first order peak. λ is a wavelength of X-rays and is, for example, 1.541 Å.

2P (sin θn−sin θ0)=±nλ (1)

A period P of core layer 12 is determined based on an interval (angle) between peaks of the rocking curve (step S12 in FIG. 3). When the first order peak is too close to the zero order peak, the peaks cannot be separated, so that evaluation of period P is difficult. Even when the period is large, the period can be evaluated provided that an angular resolution of X-ray diffraction is high.

FIG. 7B is a diagram illustrating a relationship between period P of core layer 12 and a diffraction angle of the first order peak. A horizontal axis represents period P. A vertical axis represents a diffraction angle of the first order peak. The relationship of FIG. 7B is calculated using equation (1) above. As illustrated in FIG. 7B, the smaller period P, the larger diffraction angle. The larger period P, the smaller diffraction angle. When the angular resolution of X-ray diffraction is 0.01°, period P up to about 440 nm can be evaluated by X-ray diffraction.

A peak position in the rocking curve is determined with an accuracy of ±0.0001°, for example. As an example, based on the accuracy of the peak position, period P is estimated in a range from 199.1 nm to 200.9 nm with 200 nm as a center, that is, with an error in a range of about ±1 nm. When thickness T of core layer 12 is 2000 nm, period P can be measured with an accuracy of about ±0.05%. When period P is small, the peaks are separated from each other, the peak position can be accurately measured, resulting in improving a measurement accuracy of thickness.

According to the present embodiment, core layer 12 is the superlattice layer and includes the plurality of InP layers 40 and the plurality of InGaAsP layers 42. As illustrated in FIG. 2B, thicknesses T1 of the plurality of InP layers 40 are equal to each other. Thicknesses T2 of the plurality of InGaAsP layers 42 are equal to each other. The period in core layer 12 can be measured by X-ray diffraction. Thicknesses T1 of InP layers 40, thicknesses T2 of InGaAsP layers 42, and the number of pairs are determined based on manufacturing conditions. Thickness T of core layer 12 can be calculated based on the period. That is, the thickness of core layer 12 can be evaluated by X-ray diffraction, which is a non-destructive inspection.

A distribution of light in semiconductor laser device 100 is affected by thickness T of core layer 12. Thickness T of core layer 12 is evaluated by X-ray diffraction, and thickness T is set to an appropriate value. This enables control of the distribution of light. Light is distributed in core layer 12 and kept away from active layer 18 and p-type cladding layer 28. Light absorption by active layer 18 and cladding layer 28 is suppressed, and the output of semiconductor laser device 100 is increased.

For example, thicknesses T1 of InP layers 40 and thicknesses T2 of InGaAsP layers 42 can be measured with TEM. Thicknesses T1 and T2 are measured using a TEM to obtain growth conditions under which InP layers 40 and InGaAsP layers 42 have desired thicknesses. Core layer 12 is grown under the growth conditions. The number of pairs included in core layer 12 is determined based on manufacturing conditions. Period P of core layer 12 is measured by X-ray diffraction. Thickness T of core layer 12 is obtained based on the number of pairs and period P. Thickness T of core layer 12 can be evaluated using X-ray diffraction, which is the non-destructive inspection.

The X-ray diffraction is performed after formation of core layer 12 and before formation of active layer 18. Active layer 18 has a periodic structure. When the X-ray diffraction is performed after formation of active layer 18, a rocking curve caused by the periodic structure of active layer 18 is observed together with a rocking curve caused by the periodic structure of core layer 12. Since the two rocking curves overlap with each other, it is difficult to measure the period of core layer 12. The X-ray diffraction is performed on core layer 12 before formation of active layer 18 to observe the rocking curve caused by core layer 12, so that period P of core layer 12 can be measured.

The refractive index of core layer 12 is higher than the refractive index of cladding layer 20 and the refractive index of cladding layer 28. Therefore, light is easily distributed in core layer 12, and light absorption by active layer 18 and cladding layer 28 is suppressed. The bandgap wavelength of core layer 12 is shorter than the wavelength of light generated in active layer 18. Light absorption by core layer 12 is suppressed.

Core layer 12 includes InP layers 40 and InGaAsP layers 42. Each of the plurality of InP layers 40 has a constant thickness T1. Each of the plurality of InGaAsP layers 42 has a constant thickness T2. Therefore, the period of core layer 12 can be measured by X-ray diffraction. Core layer 12 is formed of InP layers 40 and InGaAsP layers 42, which enables lattice matching between substrate 10 formed of InP and core layer 12. Core layer 12 may be formed of semiconductors other than InP and InGaAsP. For example, an aluminum indium gallium arsenide (AllnGaAs) layer may be used instead of InGaAsP layer 42. Core layer 12 may be formed of semiconductors which allows lattice matching between core layer 12 and substrate 10.

Each of thicknesses T1 of InP layers 40 and thicknesses T2 of InGaAsP layers 42 is 10 nm or more, for example. When the thicknesses are less than the 10 nm, physical properties change due to a quantum effect. In order to stabilize physical properties of core layer 12, each of thicknesses T1 and T2 is set to 10 nm or more.

Thickness T of entire core layer 12 may be, for example, 1 μm or more, 1.5 μm or more, or 1.8 μm or more. Light is kept away from p-type cladding layer 28, and thus less likely to be absorbed. Thickness T of core layer 12 is, for example, 2 μm or less. When core layer 12 is too thick, the overlap of the light distribution with active layer 18 becomes too small, resulting in decreased gain of semiconductor laser device 100. As a result, light output decreases.

As illustrated in FIG. 2A, n-type core layer 12, active layer 18, and p-type cladding layer 28 are stacked in this order. The central portion of core layer 12 and active layer 18 form mesa 11. Current flows through mesa 11, and carriers are injected into active layer 18, which causes active layer 18 to generate light. Semiconductor laser device 100 functions as a light emitting device. A width W2 of core layer 12 is larger than width W1 of mesa 11. The effective refractive index of core layer 12 is increased. Causing light to transit to core layer 12 enables suppression of light absorption.

Buried layer 24 and buried layer 26 are provided on both sides of mesa 11. Since buried layer 24 and buried layer 26 block the current, the current can be selectively supplied to mesa 11.

Mesa 11 of core layer 12 includes 10 pairs of InP layer 40 and InGaAsP layer 42. Twenty pairs of InP layer 40 and InGaAsP layer 42 are disposed below mesa 11. The number of pairs disposed below mesa 11 is larger than the number of pairs included in mesa 11. In other words, a portion of core layer 12 below mesa 11 is thicker than a portion of core layer 12 included in mesa 11. Light is distributed in core layer 12 below mesa 11 and kept away from active layer 18 and p-type cladding layer 28. Light absorption is suppressed. The number of pairs included in mesa 11 may be five or more. When the number of pairs is small, the distribution of light excessively spreads in a lateral direction (Y-axis direction), so that the gain of semiconductor laser device 100 is reduced to decrease the optical output.

Substrate 10 and core layer 12 are n-type semiconductors and are provided below active layer 18. Cladding layers 20 and 28 are p-type semiconductor layers and are provided above active layer 18. Current flows through active layer 18. Carriers are injected into active layer 18 to generate light. Light is distributed in n-type core layer 12 and kept away from the p-type cladding layers 20 and 28. This allows suppression of light absorption.

The embodiments according to the present disclosure have been described above in detail. However, the present disclosure is not limited to the specific embodiments, and various modifications and changes can be made within the scope of the gist of the present disclosure described in the claims.

What is claimed is:

1. A semiconductor laser device comprising:
a first semiconductor layer; and
an active layer provided above the first semiconductor layer,
wherein the first semiconductor layer is a superlattice layer and includes a plurality of first layers and a plurality of second layers,
the plurality first layers and the plurality of second layers are alternately stacked upon each other,
thicknesses of the plurality of first layers are equal to each other, and
thicknesses of the plurality of second layers are equal to each other.

2. The semiconductor laser device according to claim 1,
wherein the first layers are formed of indium phosphide, and
the second layers are formed of indium gallium arsenide phosphide or aluminum indium gallium arsenide.

3. The semiconductor laser device according to claim 1, further comprising:
a second semiconductor layer provided above the active layer,
wherein a refractive index of the first semiconductor layer is higher than a refractive index of the second semiconductor layer.

4. The semiconductor laser device according to claim 1,
wherein each of the thicknesses of the first layers and the thicknesses of the second layers is 10 nm or more.

5. The semiconductor laser device according to claim 1,
wherein the first semiconductor layer has a thickness of 1 μm or more.

6. The semiconductor laser device according to claim 1,
wherein the active layer forms a mesa, and
the first semiconductor layer has a width larger than a width of the mesa.

7. The semiconductor laser device according to claim 6, further comprising:
a second semiconductor layer provided above the active layer,
wherein a conductive type of the first semiconductor layer is n-type, and
a conductive type of the second semiconductor layer is p-type.

8. The semiconductor laser device according to claim 6, further comprising:
a buried layer provided on both sides of the mesa.

9. A method of manufacturing a semiconductor laser device, the method comprising:
providing a first semiconductor layer;
measuring a thickness of the first semiconductor layer by X-ray diffraction; and
providing an active layer above the first semiconductor layer after the measuring the thickness is performed,
wherein the first semiconductor layer is a superlattice layer and includes a plurality of first layers and a plurality of second layers,
the plurality first layers and the plurality of second layers are alternately stacked upon each other,
thicknesses of the plurality of first layers are equal to each other, and
thicknesses of the plurality of second layers are equal to each other.
